(19) United States
(12) Patent Application Publication
(10) Pub. No.: US 2022/0158129 A1
(43) Pub. Date: May 19, 2022

(54) DISPLAY DEVICE

(71) Applicant: SAMSUNG DISPLAY CO., LTD., YONGIN-SI (KR)

(72) Inventors: MIYOUNG KIM, HWASEONG-SI (KR); YONG-HWAN PARK, HWASEONG-SI (KR); KWANGHYEOK KIM, CHEONAN-SI (KR); SOYEON PARK, YONGIN-SI (KR); SANGHYUN JUN, SUWON-SI (KR)

(21) Appl. No.: 17/508,102

(22) Filed: Oct. 22, 2021

(30) Foreign Application Priority Data
Nov. 19, 2020 (KR) 10-2020-0155986

(51) Int. Cl. H01L 51/52; H01L 27/32; G06F 3/044

(52) U.S. Cl. CPC H01L 51/5253; G06F 3/0446; H01L 27/323

(57) ABSTRACT

A display device includes a substrate, a pixel disposed on the substrate, a thin-film encapsulation layer disposed on the pixel, a cover layer disposed on the thin-film encapsulation layer and in which an opening is defined, and a sensing part disposed on the cover layer. A recess part may be defined on an upper surface of the thin-film encapsulation layer overlapping the opening.

### CROSS-REFERENCE TO RELATED APPLICATIONS

This U.S. non-provisional patent application claims priority under 35 U.S.C. § 119 to Korean Patent Application No. 10-2020-0155986, filed on Nov. 19, 2020, the disclosure of which is hereby incorporated by reference in its entirety.

### TECHNICAL FIELD

Embodiments of the present disclosure relate to a display device.

### DISCUSSION OF RELATED ART

Electronic devices such as smartphones, digital cameras, notebook computers, navigation systems, smart televisions, etc., which provide images to users, include a display device for displaying images. The display device generates images and provides the generated images to users through a display screen.

The display device may include a display panel for generating images and an input sensor disposed on the display panel for sensing external inputs. The display panel may include a plurality of pixels for displaying images. The pixels may generate light to display images. The input sensor may include a plurality of sensing electrodes to sense external inputs.

### SUMMARY

Embodiments of the present inventive concept provide a display device capable of reducing thickness and increasing light emitting efficiency.

An embodiment of the inventive concept provides a display device including a substrate, a pixel disposed on the substrate, a thin-film encapsulation layer disposed on the pixel, a cover layer disposed on the thin-film encapsulation layer and in which t opening is defined, and a sensing part disposed on the cover layer. A recess part may be defined on an upper surface of the thin-film encapsulation layer overlapping the opening.

An embodiment of the inventive concept provides a display device including a substrate, a pixel disposed on the substrate, a connection electrode spaced apart from the pixel and disposed on the substrate, a first inorganic encapsulation layer disposed on the pixel and extending above the connection electrode, a second inorganic encapsulation layer disposed on the first inorganic encapsulation layer, a cover layer disposed on the second inorganic encapsulation layer, and a sensing part disposed as a single layer on the cover layer. The sensing part is connected to the connection electrode through a contact hole defined in the cover layer and the first and second inorganic encapsulation layers. A thickness of a portion of the second inorganic encapsulation layer disposed on the connection electrode is smaller than that of a portion of the second inorganic encapsulation layer disposed on the pixel.

### BRIEF DESCRIPTION OF THE DRAWINGS

The above and other features of the present inventive concept will become more apparent by describing in detail embodiments thereof with reference to the accompanying drawings, in which:

FIG. 1 is a perspective view of a display device according to an embodiment of the inventive concept;

FIG. 2 illustrates a cross-section of the display device illustrated in FIG. 1 according to an embodiment of the inventive concept;

FIG. 3 illustrates a cross-section of the display panel illustrated in FIG. 2 according to an embodiment of the inventive concept;

FIG. 4 is a plan view of the display panel illustrated in FIG. 2 according to an embodiment of the inventive concept;

FIG. 5 illustrates a cross-section of one pixel illustrated in FIG. 4 according to an embodiment of the inventive concept;

FIG. 6 is a plan view of an input sensor illustrated in FIG. 2 according to an embodiment of the inventive concept;

FIG. 7 shows a configuration of one first sensing part and one second sensing part illustrated in FIG. 6 according to an embodiment of the inventive concept;

FIG. 8 is a cross-sectional view taken along line I-I′ illustrated in FIG. 7 according to an embodiment of the inventive concept;

FIG. 9 is a cross-sectional view taken along line II-II′ illustrated in FIG. 7 according to an embodiment of the inventive concept;

FIG. 10 illustrates a cross-section of a portion including a display panel and an input sensor illustrated in FIG. 2 according to an embodiment of the inventive concept;

FIG. 11 illustrates a cross-section of a bending region and first and second regions adjacent to the bending region illustrated in FIGS. 4 and 6 according to an embodiment of the inventive concept;

FIG. 12 is a plan view of a cover layer which defines openings illustrated in FIG. 11 according to an embodiment of the inventive concept;

FIG. 13 is a cross-sectional view illustrating a connection structure of a first signal line, in which the connection structure extends the first signal line to a second region via a bending region illustrated in FIG. 6, according to an embodiment of the inventive concept;

FIG. 14 is a cross-sectional view illustrating a connection structure of a second pad illustrated in FIG. 6 according to an embodiment of the inventive concept;

FIGS. 15A to 15D are cross-sectional views illustrating a non-display region adjacent to a bending region illustrated in FIG. 13 according to an embodiment of the inventive concept, and are referred to in describing an effect of the implementation of a cover layer used in FIG. 13;

FIG. 16 illustrates a cross-section of a camera and the surroundings of the camera illustrated in FIG. 1 according to an embodiment of the inventive concept;

FIG. 17 illustrates a cross-section of a camera and the surroundings of the camera illustrated in FIG. 1 according to an embodiment of the inventive concept;

FIG. 18 illustrates a cross-section of a camera and the surroundings of a camera illustrated in FIG. 1 according to an embodiment of the inventive concept; and

FIG. 19 is an enlarged view illustrating one metal pattern illustrated in FIG. 18 according to an embodiment of the inventive concept.

### DETAILED DESCRIPTION

Embodiments of the present inventive concept will be described more fully hereinafter with reference to the accompanying drawings. Like reference numerals may refer to like elements throughout the accompanying drawings.

It will be understood that when a component such as a film, a region, a layer, or an element, is referred to as being “on”, “connected to”, “coupled to”, or “adjacent to” another component, it can be directly on, connected, coupled, or adjacent to the other component, or intervening components may be present. It will also be understood that when a component is referred to as being “between” two components, it can be the only component between the two components, or one or more intervening components may also be present. It will also be understood that when a component is referred to as “covering” another component, it can be the only component covering the other component, or one or more intervening components may also be covering the other component. Other words used to describe the relationships between components should be interpreted in a like fashion.

As used herein, the term “and/or” includes any and all combinations that the associated configurations can define.

It will be understood that the terms “first,” “second,” “third,” etc. are used herein to distinguish one element from another, and the elements are not limited by these terms. Thus, a “first” element in an embodiment may be described as a “second” element in another exemplary embodiment.

As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be further understood that the terms “include”, “including”, and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Herein, when two or more elements or values are described as being substantially the same as or about equal to each other, it is to be understood that the elements or values are identical to each other, the elements or values are equal to each other within a measurement error, or if measurably unequal, are close enough in value to be functionally equal to each other as would be understood by a person having ordinary skill in the art. For example, the term “about” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations as understood by one of the ordinary skill in the art. Further, it is to be understood that while parameters may be described herein as having “about” a certain value, according to exemplary embodiments, the parameter may be exactly the certain value or approximately the certain value within a measurement error as would be understood by a person having ordinary skill in the art. Other uses of these terms and similar terms to describe the relationships between components should be interpreted in a like fashion.

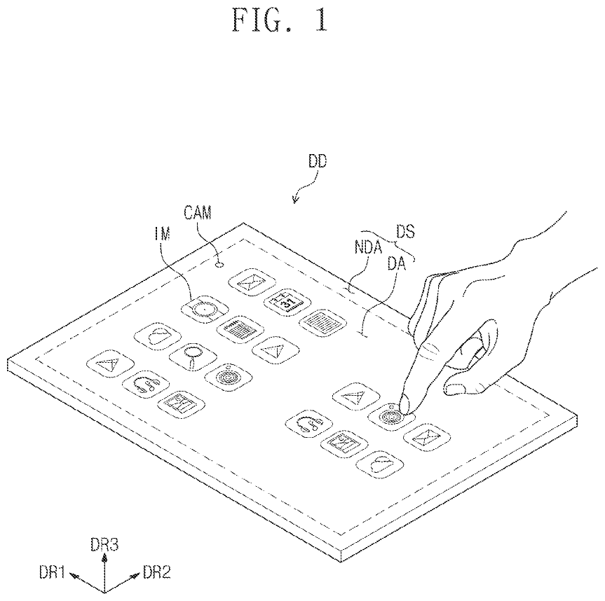

FIG. 1 is a perspective view of a display device according to an embodiment of the inventive concept.

Referring to FIG. 1, the display device DD according to an embodiment of the inventive concept may have a rectangular shape having long sides extending in a first direction DR1 and short sides extending in a second direction DR2 crossing the first direction DR1. However, the display device DD is not limited thereto, and may have various shapes such as, for example, a circle or a polygon.

Hereinafter, a direction substantially perpendicular to a plane defined by the first and second directions DR1 and DR2 is defined as a third direction DR3. In addition, in this specification, the meaning of being viewed on a plane is defined as being viewed in the third direction DR3.

The upper surface of the display device DD may be defined as a display surface DS and have a plane defined by the first direction DR1 and the second direction DR2. Images IM generated and displayed through the display surface DS of the display device DD may be provided to a user.

The display surface DS may include a display region DA and a non-display region NDA around the display region DA. Images IM may be displayed in the display region DA, and are not displayed in the non-display region NDA. The non-display region NDA may surround the display region DA and define a border of the display device DD. The non-display region may be printed in a predetermined color.

The display device DD may include at least one camera CAM. The camera CAM may be disposed within the display region DA. As an example, the camera CAM may be adjacent to the upper surface of the display region DA. However, the location of the camera CAM is not limited thereto.

The display device DD may be used for a large-sized electronic device such as, for example, a television, a monitor, or an external billboard. In addition, the display device DD may also be used for a small-sized or medium-sized electronic device such as, for example, a personal computer, a laptop computer, a personal digital terminal, a vehicle navigation unit, a game machine, a smartphone, a tablet, or a camera. However, these are only presented as examples, and the display device DD may also be used for other electronic devices according to embodiments of the present inventive concept.

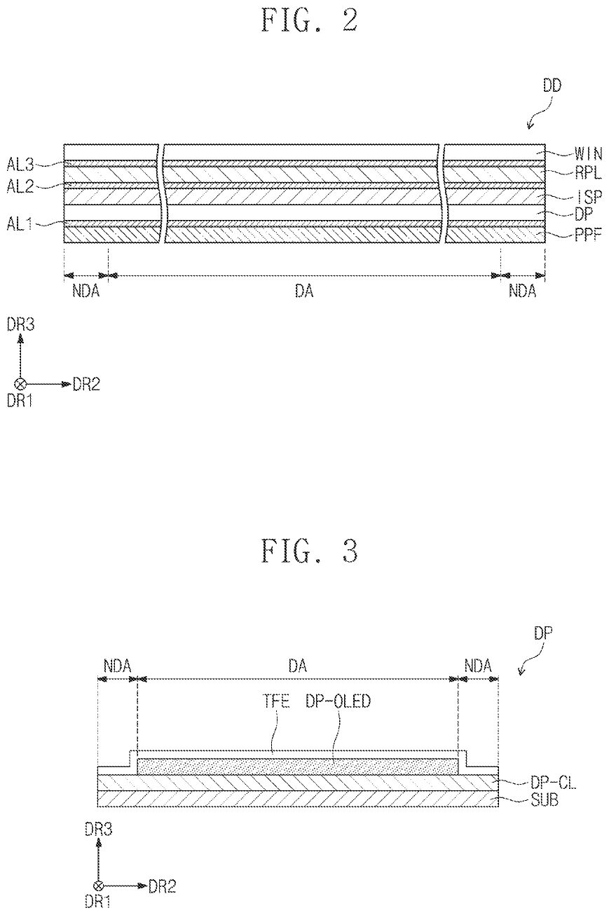

FIG. 2 illustrates a cross-section of the display device DD illustrated in FIG. 1 according to an embodiment of the inventive concept.

As an example, FIG. 2 illustrates a cross-section of the display device DD viewed in the first direction DR1.

Referring to FIG. 2, the display device DD may include a display panel DP, an input sensor ISP, a reflection prevention layer RPL, a window WIN, a panel protection film PPF, and first to third insulating layers AL1 to AL3.

The display panel DP may be a flexible display panel. The display panel DP according to an embodiment of the inventive concept may be a light-emitting display panel, but is not particularly limited thereto. For example, the display panel DP may be an organic light-emitting display panel or a quantum dot light-emitting display panel. A light-emitting layer of the organic light-emitting display panel may include an organic light-emitting material. A light-emitting layer of the quantum dot light-emitting display panel may include quantum dots, quantum rods, and the like. Hereinafter, the display panel DP will be described as an organic light-emitting display panel. However, embodiments of the inventive concept are not limited thereto.

The input sensor ISP may be disposed on the display panel DP. The input sensor ISP may include a plurality of sensors that sense an external input by a capacitive method. When the display device DD is manufactured, be input sensor ISP may be manufactured directly on the display panel DP. However, embodiments of the inventive concept are not limited thereto. For example, in an embodiment, the input sensor ISP may be manufactured as a panel independent of the display panel DP and then attached to the display panel DP by an adhesive layer.

The reflection prevention layer RPL may be disposed on the input sensor ISP. The reflection prevention layer RPL may be defined as an external-light reflection prevention film. The reflection prevention layer RPL may reduce the reflectance of external light incident toward the display panel DP from above the display device DD.

When external light traveling toward the display panel DP is reflected from the display panel DP and provided again to an external user, the external light may he visually recognized to a user. To prevent or reduce such a phenomenon, as an example, the reflection prevention layer RPL may include a plurality of color filters that display the same colors as the pixels of the display panel DP.

The color filters may filter external light so as to display the same colors as the pixels. In this case, in embodiments, the external light is not visible to the user or may be less visible to the user. However, the reflection prevention layer RPL is not limited thereto. For example, according to embodiments, the reflection prevention layer RPL may include a retarder and/or a polarizer that reduce the reflectance of the external light.

The window WIN may be disposed on the reflection prevention layer RPL. The window WIN may protect the display panel DP, the input sensor ISP, and the reflection prevention layer RPL from external impact such as, for example, a scratch.

The panel protection film PPF may be disposed below the display panel DP. The panel protection film PPF may protect the lower portion of the display panel DP. The panel protection film PPF may include a flexible plastic material such as polyethylene terephthalate (PET).

A first adhesive layer AL1 may be disposed between the display panel DP and the panel protection film PPF. The display panel DP and the panel protection film PPF may be adhered to each other by the first adhesive layer AL1.

A second adhesive layer AL2 may be disposed between the reflection prevention layer RPL and the input sensor ISP. The reflection prevention layer RPL and the input sensor ISP may be adhered to each other by the second adhesive layer AL2.

A third adhesive layer AL3 may be disposed between the window WIN and the reflection prevention layer RPL. The window WIN and the reflection prevention layer RPL may be adhered to each other by the third adhesive layer AL3.

FIG. 3 illustrates a cross-section of the display panel DP illustrated in FIG. 2 according to an embodiment of the inventive concept.

As an example, FIG. 3 illustrates a cross-section of the display panel DP viewed in the first direction DR1.

Referring to FIG. 3, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include the display region DA and the non-display region NDA around the display region DA. The substrate SUB may include a flexible plastic material such as, for example, polyimide (PI). The display element layer DP-OLED may be disposed in the display region DA.

A plurality of pixels may be disposed in the circuit element layer DP-CL and the display element layer DP-OLED. Each of the pixels may include a transistor disposed on the circuit element layer DP-CL and a light-emitting diode, disposed on the display element layer DP-OLED and connected to the transistor. Hereinafter, the configuration of the pixel will be described in detail.

The thin-film encapsulation layer TFE may be disposed on the circuit element layer DP-CL so as to cover the display element layer DP-OLED. The thin-film encapsulation layer TFE may include inorganic layers and organic layers between the inorganic layers. The inorganic layers may protect the pixels PX from moisture/oxygen. The organic layers may protect the pixels PX from foreign substances such as, for example, dust particles.

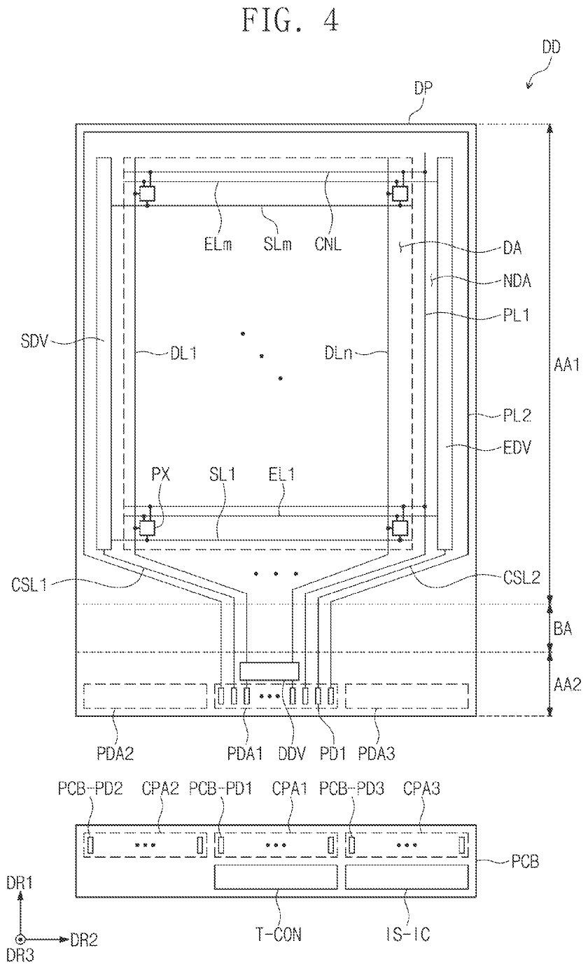

FIG. 4 is a plan view of the display panel DP illustrated in FIG. 2 according to an embodiment of the inventive concept.

Referring to FIG. 4, the display device DD may include the display panel DP, a scan driver SDV, a data driver DDV, a light emission driver EDV, a printed circuit board PCB, a timing controller T-CON, and an input sensor controller IS-IC.

The display panel DP may be a flexible display panel. The display panel DP may extend longer in the first direction DR1 than in the second direction DR2. For example, the display panel DP may have a rectangular shape having long sides extending in the first direction DR1 and short sides extending in the second direction DR2.

The display panel DP may include a first region AA1, a second region AA2, and a bending region BA disposed between the first region AA1 and the second region AA2. The bending region BA may extend in the second direction DR2, and the first region AA1, the bending region BA, and the second region AA2 may be arranged in the first direction DR1.

The first region AA1 may extend in the first direction DR1 and have long sides opposite to each other in the second direction DR2. The first region AA1 may include the display region DA and the non display region NDA around the display region DA. As described above, in an embodiment, the non-display region NDA may surround the display region DA, images may be displayed in the display region DA, and images are not displayed in the non-display region NDA. The second region AA2 and the bending region BA may be regions in which images are not displayed.

The display panel DP may include a plurality of pixels PX, a plurality of scan lines SL1 to SLm, a plurality of data lines DLI to DLn, a plurality of light emission lines EL1 to ELm, first and second control lines CSL1 and CSL2, a first power line PL1, a second power line PL2, connection lines CNL, and a plurality of first pads PD1. “m” and “n” are natural numbers. The pixels PX may be disposed in the display region DA and connected to the scan lines SL1 to SLm, data lines DL1 to DLn, and light emission lines EL1 to ELm.

The scan driver SDV and the light emission driver EDV may be disposed in the non-display region NDA. The scan driver SDV and the light emission driver EDV may be disposed in the non-display region NDA respectively adjacent to the long sides of the first region AA1. The data driver DDV may be disposed in the second region AA2. The data river DDV may be manufactured in the form of an integrated circuit chip and mounted in the second region AA2.

The scan lines SL1 to SLm may extend in the second direction DR2 to be connected to the scan driver SDV. The data lines DL1 to DLn may extend in the first direction DR1 from the first region AA1 to the second region AA2 via the bending region BA to be connected to the data driver DDV. The light emission lines EL1 to Elm may extend in the second direction DR2 to be connected to the light emission driver EDV.

The first power line PL1 may extend in the first direction DR1 to be disposed in the non-display region NDA. The first power line PL1 may be disposed between the display region DA and the light emission driver EDV. However, embodiments of the inventive concept are not limited thereto. For example, in an embodiment, the first power line PL1 may be disposed between the display region DA and the scan driver SDV.

The first power line PL1 may extend to the second region AA2 via the bending region BA. When viewed on a plane, the first power line PL1 may extend toward the lower end of the second region AA2. The first power line PL1 may receive a first voltage.

The second power line PL2 may be disposed in the non-display region NDA facing the second region AA2 with the display region DA and the non-display region NDA interposed therebetween and adjacent to the long sides of the first region AA1. The second power line PL2 may be disposed outside the scan driver SDV and the light emission driver EDV.

The second power line PL2 may extend to the second region AA2 via the bending region BA. The second power line PL2 may extend in the first direction DR1 in the second region AA2 with the data driver DDV therebetween. When viewed on a plane, the second power line PL2 may extend toward the lower end of the second region AA2.

The second power line PL2 may receive a second voltage which is lower than the first voltage. In an embodiment, the second power line PL2 may extend to the display region DA to be connected to pixels PX, and the second voltage may be provided to the pixels PX through the second power line PL2.

The connection lines CNL may extend in the second direction DR2 and be arranged in the first direction DR1. The connection lines CNL may be connected to the first power line PL1 and the pixels PX. The first voltage may be applied to the pixels PX through the first power line PL1 and the connection lines CNL connected to each other.

The first control line CSL1 may be connected to the scan driver SDV and extend toward the lower end of the second region AA2 via the bending region BA. The second control line CSL2 may be connected to the light emission driver EDV and extend toward the lower end of the second region AA2 via the bending region BA. The data driver DDV may be disposed between the first control line CSL1 and the second control line CSL2.

The first pad region PDA1, a second pad region PDA2, and a third pad region PDA3 may be defined in a portion of the second region AA2 adjacent to the lower end of the second region AA2. The first pad region PDA1, the second pad region PDA2, and the third pad region PDA3 may extend and be arranged in the second direction DR2. The first pad region PDA1 may be disposed between the second pad region PDA2 and the third pad region PDA3.

The first pads PD1 may be disposed in the first pad region PDA1. The data driver DDV, the first power line PL1, the second power line PL2, the first control line CSL1, and the second control line CSL2 may be connected to the first pads PD1.

The data lines DL1 to DLn may be connected to corresponding first pads PD1 through the data driver DDV. For example, the data lines DL1 to DLn may be connected to the data driver DDV, and the data driver DDV may be connected to the first pads PD1 corresponding to the data lines DL1 to DLn, respectively.

The timing controller T-CON and the input sensor controller IS-IC may be disposed on the printed circuit board PCB. Each of the timing controller T-CON and the input sensor controller IS-IC may be manufactured as an integrated circuit chip and mounted on the printed circuit board PCB.

A first connection pad region CPA 1, a second connection pad region CPA2, and a third connection pad region CPA3 may be defined in a portion of the printed circuit board PCB, in which the portion is adjacent to one side of the printed circuit board PCB. The first connection pad region CPA1, the second connection pad region CPA2, and the third connection pad region CPA3 may extend and be arranged in the second direction DR2. The first connection pad region CPA1 may be disposed between the second connection pad region CPA2 and the third connection pad region CPA3.

First pads PCB-PD1 may be disposed in the firstpad region CPA1, second pads PCB-PD2 may be disposed in the second connection pad region CPA2, and third pads PCB-PD3 may be disposed in the third connection pad region CPA3. The first pads PD1 may be connected to the first pads PCB-PD1. The first pads PCB-PD1 may be connected to the timing controller T-CON. The second pads PCB-PD2 and the third pads PCB-PD3 may be connected to the input sensor controller IS-IC.

The timing controller T-CON may control the operation of the scan er SDV, the data driver DDV, and the light emission driver EDV. The timing controller T-CON may generate a scan control signal, a data control signal, and a light emission control signal in response to control signals received from outside of the timing controller T-CON.

The scan control signal may be provided to the scan driver SDV through the first control line CSL1. The light emission control signal may be provided to the light emission driver EDV through the second control line CSL2. The data control signal may be provided to the data driver DDV. The timing controller T-CON may receive image signals from outside of the timing controller T-CON, convert the data format of the image signals to meet the specifications of an interface with the data driver DDV, and provide the converted image signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The light emission driver EDV may generate a plurality of light emission signals in response to the light emission control signal. The light emission signals may be applied to the pixels PX through the light emission lines EL1 to Elm.

The pixels PX may receive the data voltages in response to the scan signals. The pixels PX may display an image by emitting light having brightness corresponding to the data voltages in response to the light emission signals. The light emission time of the pixels PX may be controlled by the light emission signals.

In art embodiment, the bending region BA may be bent so that the second region AA2 may be disposed below the first region AA1. Accordingly, the data driver DDV may be disposed below the first region AA1, thus, not being visually recognizable to a user.

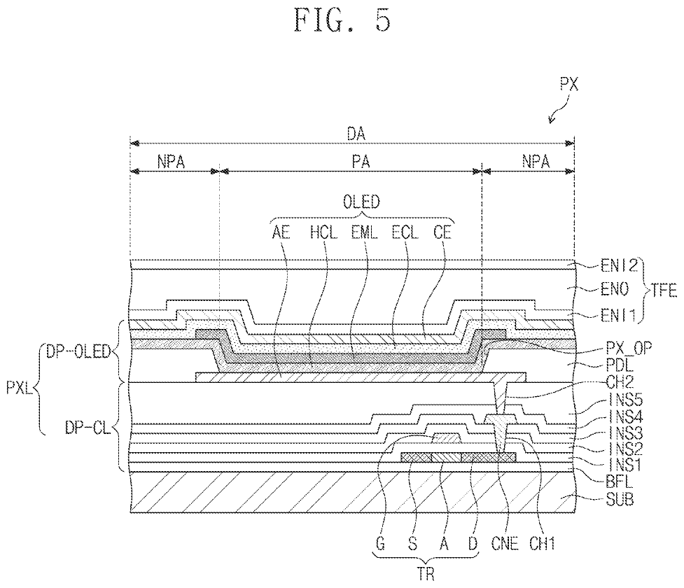

FIG. 5 illustrates a cross-section of one pixel PX illustrated in FIG. 4 according to an embodiment of the inventive concept.

Referring to FIG. 5, a pixel PX may be disposed on the substrate SUB and include a transistor TR and a light-emitting diode OLED. The light-emitting diode OLED may include a first electrode AE, a second electrode CE, a hole control layer HCL, an electron control layer ECL, and a light-emitting layer EML. The first electrode AE may be an anode electrode, and the second electrode CE may be a cathode electrode.

The transistor TR and the light-emitting diode OLED may be disposed on the substrate SUB. Although one transistor TR is illustrated as an example, the pixel PX may include a plurality of transistors and at least one capacitor for driving the light emitting diode OLED.

The display region DA may include a light-emitting region PA corresponding to the pixel PX and a non-light-emitting region NPA around the light-emitting region PA. The light-emitting diode OLED may be disposed in the light-emitting region PA.

The substrate SUB may include a flexible plastic substrate. For example, the substrate SUB may include transparent polyimide (PI). A buffer layer BFL may be disposed on the substrate SUB. The buffer layer BFL may be an inorganic layer. A semiconductor pattern may be disposed on the buffer layer BFL. The semiconductor pattern may include polysilicon. However, embodiments of the inventive concept are not limited thereto. For example, according to embodiments, the semiconductor pattern may include amorphous silicon or metal oxide.

The semiconductor pattern may be doped with an N-type dopant or a P-type dopant. The electrical properties of the semiconductor pattern may vary depending on whether the semiconductor pattern is doped. The semiconductor pattern may include a highly doped region and a lightly doped region. The conductivity of the highly doped region may be greater than that of the lightly doped region, and may substantially serve as a source electrode and a drain electrode of the transistor TR. The lightly doped region may substantially correspond to the active region (or channel) of the transistor.

A source S, active region A, and drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may be disposed between the transistor TR and the light-emitting diode OLED to connect the transistor TR and the light-emitting diode OLED. The connection electrode CNE may be disposed on the third insulating layer INS3 and connected to the drain D through a first contact hole CH1 defined in the first to third insulating layers INS1 to INS3. A fourth insulating layer INS4 may be disposed on the connection electrode CNE. A fifth insulating layer INS5 may be disposed on the fourth insulating layer INS4.

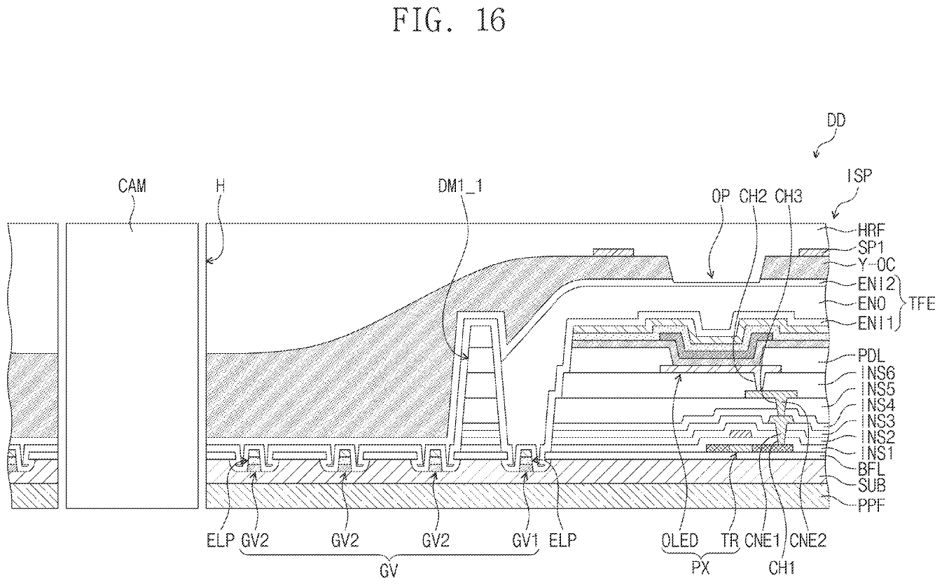

In an embodiment, the connection electrode CNE may be one of a plurality of connection electrodes CNE. A structure in which a plurality of connection electrodes CNE is provided will be described with reference to FIGS. 16 to 18 below.

The first to fourth insulating layers INS1 to INS4 may be inorganic layers, and the fifth insulating layer INS5 may be an organic layer.

The first electrode AE may be disposed on the fifth insulating layer INS 5. The first electrode AE may be connected to the connection electrode CNE through a second contact hole CH2 defined in the fifth insulating layer INS5. A pixel-defining film PDL exposing a predetermined portion of the first electrode AE may be disposed on the first electrode AE and the fifth insulating layer INS5. An opening PX_OP that exposes the predetermined portion of the first electrode AE may be defined in the pixel-defining film PDL.

The hole control layer HCL may be disposed on the first electrode AE and the pixel-defining film PDL. The hole control layer HCL may be commonly disposed in the light-emitting region PA and the non-light-emitting region NPA. The hole control layer HCL may include a hole transport and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic. material. The light-emitting layer EML may generate any one of red, green, and blue light.

The electron control layer ECL may be disposed on the light-emitting layer EML and the hole control layer HCL. The electron control layer ECL may be commonly disposed in the light-emitting region PA and the non-light-emitting region NPA. The electron control layer ECL may include a hole transport layer and a hole injection layer.

The second electrode CE may be disposed on the electron control layer ECL. The second electrode CE may be commonly disposed in the pixels PX. A layer from the buffer layer BFL to the light-emitting diode OLED may be defined as a pixel layer PXL.

The thin-film encapsulation layer TFE may be disposed on the light-emitting diode OLED. The thin-film encapsulation layer TFE may be disposed on the second electrode CE and cover the pixel PX. The thin-film encapsulation layer TFE may include a first inorganic encapsulation layer ENI1 disposed on the pixel PX, a second inorganic encapsulation layer ENI2 disposed on the first inorganic encapsulation layer ENI1, and an organic encapsulation layer ENO disposed between the first and second inorganic encapsulation layers ENI1 and ENI2.

The first and second inorganic encapsulation layers ENI1 and ENI2 may include an inorganic material and protect the pixels from moisture/oxygen. The organic encapsulation layer ENO may include an organic material and protect the pixels from foreign substances such as, for example, dust particles.

A first voltage may be applied to the first electrode AE through the transistor TR, and a second voltage lower than the first voltage may be applied to the second electrode CE. Holes and electrons injected into the light-emitting layer EML may be combined to form excitons, and while the excitons transition to the ground state, the light-emitting diode OLED may emit light.

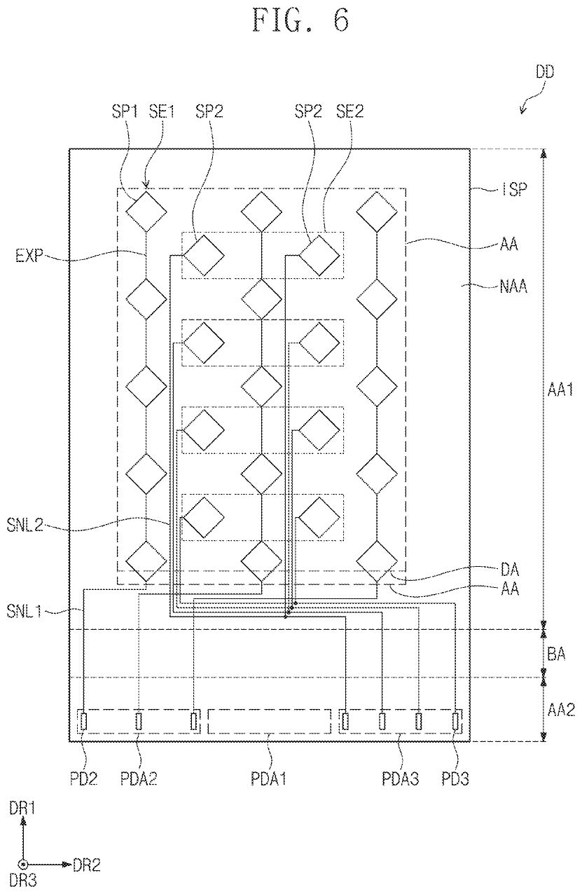

FIG. 6 is a plan view of the input sensor ISP illustrated in FIG. 2 according to an embodiment of the inventive concept.

Referring to FIG. 6, the display device DD may include the input sensor ISP. The input sensor ISP may include a plurality of sensing electrodes SE1 and SE2, a plurality of lines SNL1 and SNL2, and a plurality of second and third pads PD2 and PD3. The plurality of sensing electrodes SE1 and SE2, the plurality of lines SNL1 and SNL2, and the plurality of second and third pads PD2 and PD3 may be disposed on the thin-film encapsulation layer TFE.

Like the display panel DP, the plane region of the input sensor ISP may include the first region AA1, the second region AA2, and the bending region BA. The first region AA1 may include an active region AA and a non-active region NAA around the active region AA. The active region AA may overlap the display region DA, and the non-active region NAA may overlap the non-display region NDA.

The active region AA may extend further than the display region DA. For example, the active region AA may extend further than the display region DA in the first direction DR1 toward the lower end of the input sensor ISP.

The sensing electrodes SE1 and SE2 may be disposed in the first region AA1 and the second and third pads PD2 and PD3 may be disposed in the second region AA2. The lines SNL1 and SNL2 may be connected to the sensing electrodes SE1 and SE2 and extend to the second region AA2 via the bending region BA. The lines SNL1 and SNL2 may be connected to the second and third pads PD2 and PD3 in the second region AA2.

The second and third pads PD2 and PD3 may be respectively connected to the second and third pads PCB-PD2 and PCB-PD3 illustrated in FIG. 4. The input sensor controller IS-IC may control the operation of the input sensor ISP.

The sensing electrodes SE1 and SE2 may include a plurality of first sensing electrodes SE1 extending in the first direction DR1 and arranged in the second direction DR2, and a plurality of second sensing electrodes SE2 extending in the second direction DR2 and arranged in the first direction DR1.

The first direction DR1 may correspond to a column direction, and the second direction DR2 may correspond to a row direction. As an example, the first sensing electrodes SE1 disposed in three columns and the second sensing electrodes SE2 arranged in four rows are illustrated in FIG. 6. However, the number of the first and second sensing electrodes SE1 and SE2 are not limited thereto.

The lines SNL1 and SNL2 may include a plurality of first signal lines SNL1 connected respectively to ends of the first sensing electrodes SE1, and a plurality of second signal lines SNL2 connected to the second sensing electrodes SE2. The first signal lines SNL1 may be connected to the second pads PD2, and the second signal lines SNL2 may be connected to the third pads PD3.

Like the display panel DP, the first pad region PDA1, the second pad region PDA2, and the third pad region PDA3 may be defined in a portion of the second region AA2 of the input sensor ISP, in which the portion is adjacent to the lower end of the second region AA2. The second pads PD2 may be disposed in the second pad region PDA2, and the third pads PD3 may be disposed in the third pad region PDA3.

Each of the first sensing electrodes SE1 may include a plurality of first sensing parts SP1 arranged in the first direction DR1 and a plurality of extension units EXP extending from the first sensing parts SP1. Each of the extension units EXP may be disposed between two first sensing parts SP1 adjacent to each other in the first direction DR1. Each of the first signal lines SNL1 may be connected to a first sensing part SP1 disposed at the lower end of a corresponding first sensing electrode SE1 among the first sensing electrodes SE1.

Each of the second sensing electrodes SE2 may include a plurality of second sensing parts SP2 arranged in the second direction DR2. The second signal lines SNL2 may be respectively connected to the second sensing parts SP2. The second signal lines SNL2 respectively connected to the second sensing parts SP2 disposed in a same row may he connected to each other between the active region AA and the bending region BA. Therefore, the second sensing parts SP2 disposed in the same row may be electrically connected to each other.

When viewed on a plane, the first signal lines SNL1 and the second signal lines CNL2 may cross each other between the active region AA and the bending region BA. The first signal lines SNL1 and the second signal lines CNL2 crossing each other may be disposed in different layers and insulated from each other.

Without overlapping each other, the first sensing parts SP1 and the second sensing parts SP2 may be spaced apart from each other and alternately disposed with each other. An electrostatic capacitor may be formed by the first sensing parts SP1 and the second sensing parts SP2. The first sensing parts SP1 and the second sensing parts SP2 may include metal. The first sensing parts SP1 and the second sensing parts SP2 may have a rhombus shape, but the shape of the first and second sensing parts SP1 and SP2 is not limited thereto.

In an embodiment, the input sensor ISP ma be driven in a mutual sensing mode. For example, the input sensing controller IS-IC may apply driving signals to the second sensing electrodes SE2 and receive sensing signals from the first sensing electrodes SE1.

In an embodiment, the input sensor ISP array be driven in a self-sensing mode. In this case, the input sensor ISP may include a plurality of sensing parts and lines connected to the sensing parts so as to correspond one-to-one to the sensing parts. When the input sensor ISP is driven in the self-sensing mode, driving signals may be applied to the sensing parts and sensing signals may be output from the sensing parts.

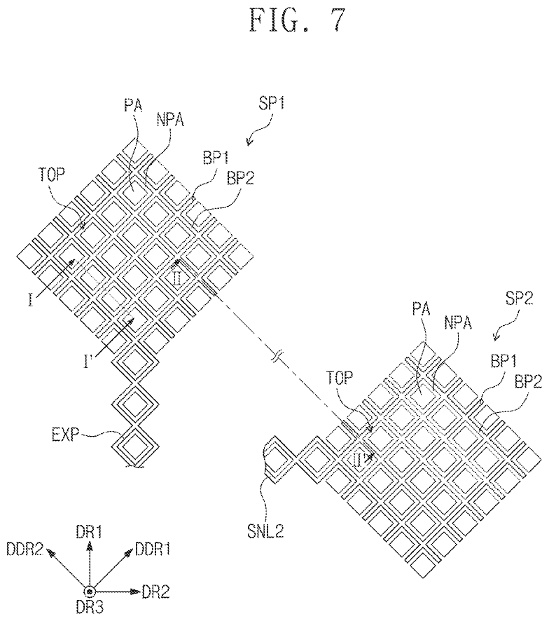

FIG. 7 shows a configuration of one first sensing part SP1 and one second sensing part SP2 illustrated in FIG. 6 according to an embodiment of the inventive concept.

As an example, FIG. 7 illustrates light-emitting regions PA and non-light-emitting regions NPA together with first and second sensing parts SP1 and SP2.

Referring to FIG. 7, the first and second sensing parts SP1 and SP2 may have a mesh shape. For example, the first and second sensing parts SP1 and SP2 may include a plurality of first branch portions BP1 extending in a first diagonal direction DDR1 and a plurality of second branch portions BP2 extending in a second diagonal direction DDR2.

The first diagonal direction DDR1 may be defined as a direction crossing the first and second directions DR1 and DR2 on a plane defined by the first and second directions DR1 and DR2. The second diagonal direction DDR2 may be defined as a direction crossing the first diagonal direction DDR1 on a plane defined by the first and second directions DR1 and DR2. As an example, the first and second directions DR1 and DR2 may form about a 90 degree angle with each other, and the first and second diagonal directions DDR1 and DDR2 may form about a 90 degree angle with each other.

The first branch portions BP1 and the second branch portion BP2 may cross each other and be integrally formed with each other. Openings TOP having a rhombus shape may be defined by the first branch portions BP1 and the second branch portions BP2 crossing each other. The first and second branch portions BP1 and BP2 may be defined as mesh lines, and the line width of each of the mesh lines may be several micrometers. The first and second branch portions BP1 and BP2 may include metal.

The extension unit EXP may have a mesh shape like the first sensing part SP1 and extend from the first sensing part SP1. The second signal line SNL2 may have a mesh shape like the second sensing part SP2 and extend from the second sensing part SP2.

The light-emitting regions PA may have a rhombus shape and may overlap the openings TOP. The first and second branch portions BP1 and BP2 may overlap the non-light-emitting region NPA. The light-emitting region PA illustrated in FIG. 5 may be one of the light-emitting regions PA illustrated in FIG. 7.

Since the first and second branch portions BP1 and BP2 are disposed in the non-light-emitting region NPA, light generated in the light-emitting region PA may be normally emitted without being affected by the first and second branch portions BP1 and BP2.

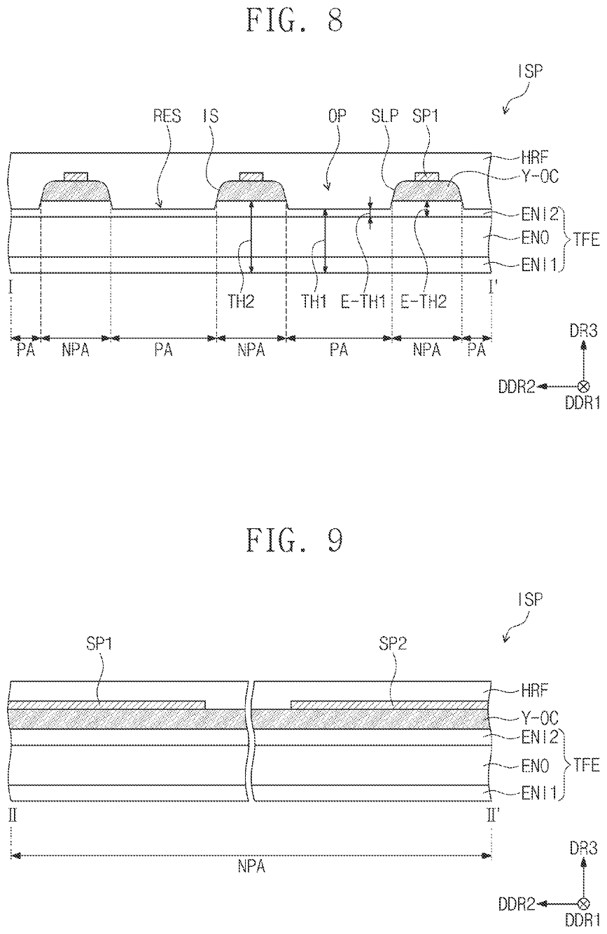

FIG. 8 is a cross-sectional view taken along line I-I′ illustrated in FIG. 7 according to an embodiment of the inventive concept. FIG. 9 is a cross-sectional view taken along line II-II′ illustrated in FIG. 7 according to an embodiment of the inventive concept.

Referring to FIGS. 8 and 9, the input sensor ISP may include a cover layer Y-OC, a refracting layer HRF, and first and second sensing parts SP1 and SP2.

The cover layer Y-OC may be disposed on the thin-film encapsulation layer TFE. For example, the cover layer Y-OC may be disposed on a second inorganic encapsulation later ENI2 of the thin-film encapsulation layer TFE. The cover layer Y-OC may include an organic layer. The cover layer Y-OC may directly contact the upper surface of the second inorganic encapsulation layer ENI-2. The cover layer Y-OC may also be referred to as an insulating layer.

A plurality of openings OP may be defined in the cover layer Y-OC. When viewed on a plane, the openings OP may overlap light-emitting regions PA. Since the above-described light-emitting diodes OLED are disposed in the light-emitting regions PA, the openings OP may overlap the light-emitting diodes OLED when viewed on a plane. Due to this structure, in an embodiment, the cover layer Y-OC may be disposed on the non-light-emitting region NPA and is not disposed on the light-emitting regions PA.

A recess part RES may be defined on a portion of the thin-film encapsulation layer TFE overlapping each of the openings OP. The recess part RES may be defined on the upper surface of the thin-film encapsulation layer TFE. Due to this structure, a first thickness TH1 of a portion of the thin-film encapsulation layer TFE overlapping each of the openings OP may be smaller than a second thickness TH2 of a portion of the thin-film encapsulation layer TFE overlapping the cover layer Y-OC.

The recess part RES may be defined on a portion of the second inorganic encapsulation layer ENI2 overlapping each of the openings OP. The recess part RES may be defined on the upper surface of the second inorganic encapsulation layer ENI2. A first thickness E-TH1 of a portion of the second inorganic encapsulation layer ENI2 overlapping each of the openings OP may be smaller than a second thickness E-TH2 of a portion of the second inorganic encapsulation layer ENI2 overlapping the cover layer Y-OC.

The recess part RES may be defined on a portion of the second inorganic encapsulation layer ENI2 overlapping each of the openings OP by etching the portion thereof. Accordingly, the height of a portion of the thin-film encapsulation layer TFE overlapping each of the openings OP may be lower than that of a portion of the thin-film encapsulation layer TFE overlapping the cover layer Y-OC.

The side surfaces of the cover layer Y-OC defining the openings OP may be defined as inner side surfaces IS and have inclined surfaces SLP. Each of the inclined surfaces SLP may extend to form an acute angle with respect to the lower surface of the cover layer Y-OC. The lower surface of the cover layer Y-OC may be a surface facing the second inorganic encapsulation layer ENI2. In an embodiment, the upper portions of the inclined surfaces SLP may form a curve and extend toward the upper surface of the cover layer Y-OC. In an embodiment, the inner side surfaces IS are not formed in a curved shape, but rather, may be formed in a linear shape.

The first and second sensing parts SP1 and SP2 may be disposed on the same layer. For example, the first and second sensing parts SP1 and SP2 may be disposed on the upper surface of the cover layer Y-OC. The first and second sensing parts SP1 and SP2 may be disposed in the same layer. In an embodiment, the extension units EXP may also be disposed in the same layer as the first and second sensing parts SP1 and SP2. Accordingly, the first and second sensing parts SP1 and SP2 and the extension units EXP may be provided as a single layer disposed on the upper surface of the cover layer Y-OC. For example, in an embodiment, the first and second sensing parts SP1 and SP2 may be formed directly on the upper surface of the cover layer Y-OC, and in an embodiment, the extension units EXP may also be formed on the upper surface of the cover layer Y-OC with the first and second sensing parts SP1 and SP2, thus forming a single layer.

Referring to a comparative example, when the first sensing parts SP1 and the second sensing parts SP2 are disposed in different layers, the thickness of the input sensor ISP may be increased. In addition, although the first sensing parts SP1 and the second sensing parts SP2 are disposed in the same layer, bridges for connecting the first sensing parts SP1 may be separately used, thus making the sensing parts disposed in different layers. In this case, the thickness of the input sensor ISP may be increased.

In an embodiment of the inventive concept, since the first and second sensing parts SP1 and SP2 and the extension units EXP are disposed as a single layer on the cover layer Y-OC, the thickness of the input sensor ISP may be reduced, thus reducing the thickness of the display device DD.

The refracting layer HRF may be disposed on the thin-film encapsulation layer TFE so as to cover the cover layer Y-OC and the first and second sensing parts SR1 and SP2. The refracting layer HRF may include an organic layer. The refracting layer HRF may have a higher refractive index than the cover layer YOC.

The first refractive index of the cover layer Y-OC may range from about 1.3 to about 1.6. In an embodiment, the first refractive index of the cover layer Y-OC may be in the range of about 1.4 to about 1.55. The cover layer Y-OC may include, for example, ethylhexyl acrylate, pentafluoropropyl acrylate, poly(ethylene glycol) dimethacrylate, ethylene glycol dimethacrylate, or the like.

In an embodiment, the cover layer (Y-OC) may include an acrylic-based organic material having a refractive index of about 1.5. In an embodiment, the cover layer Y-OC may be formed of a material forming an organic encapsulation layer ENO of the thin-film encapsulation layer TFE. In an embodiment, the cover layer Y-OC may include an epoxy-based organic material and, in some cases, a photo-curable material.

The refracting layer HRF may be defined as a planarization layer having a second refractive index. The second refractive index of the refracting layer HRF may be in the range of about 1.65 to about 1.85. The refracting layer HRF may include, for example, polydialkylsiloxane, methyltrimethoxysilane, tetramethoxysilane, or the like.

In an embodiment, the refracting layer HRF may include an acrylic-based and/or siloxane-based organic material having a refractive index of about 1.6. In an embodiment, the refracting layer HRF may include dispersed particles for a high refractive index. The refracting layer HRF array include metal oxide particles such as, for example, zinc oxide (ZnOx), titanium oxide (TiO2), or zirconium oxide (ZrO2).

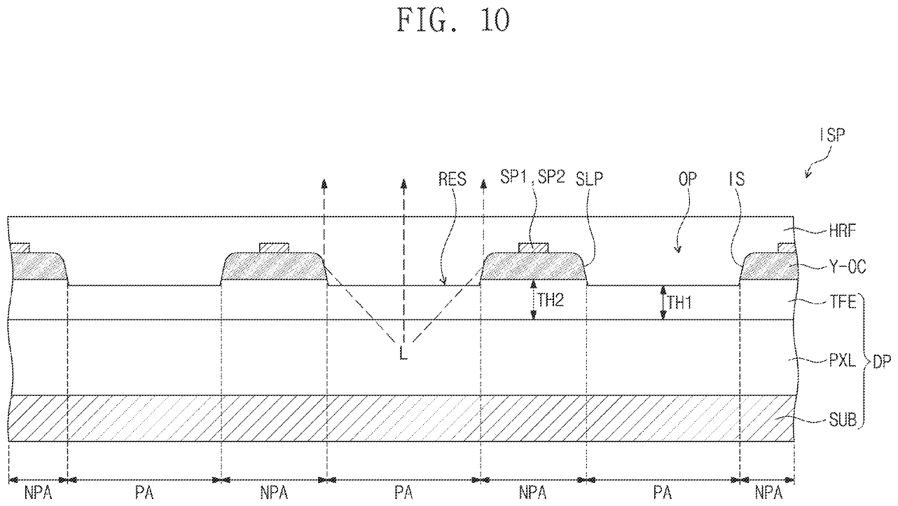

FIG. 10 illustrates a cross-section of a portion including the display panel DP and the input sensor ISP illustrated in FIG. 2 according to an embodiment of the inventive concept.

As an example, in FIG. 10, first sensing parts SP1 are illustrated, and the display panel DP is partially illustrated. For example, in FIG. 10, the circuit element layer DP-CL and the display element layer DP-OLED are simplified as the pixel layer PXL so as to be illustrated as a single layer. In addition, three light-emitting regions PA and a non-light-emitting region NPA around each of the light emitting regions PA are illustrated.

Referring to FIG. 10, light L may be generated in the pixel layer PXL. The light L may be generated in the light-emitting regions PA. For example, the light L may be generated from the above-described light-emitting diodes OLED. The light L may travel vertically upward, but some of the light L may also travel toward the cover layer Y-OC.

Since the refractive index of the refracting layer HRF is greater than that of the cover layer Y-OC, total reflection may occur at the interface between the refracting layer HRF and the cover layer Y-OC. Accordingly, the portion of the light L travelling toward inclined surfaces SLP may travel upward after being reflected from the inclined surfaces SLP of the cover layer Y-OC. As a result, front brightness may be increased in the light-emitting regions PA.

Referring to FIGS. 8 and 10, since the thickness TH1 of the thin-film encapsulation layer TFE overlapping the light-emitting region PA is smaller than that the thickness TH2 of the thin-film encapsulation layer TFE overlapping the non-light-emitting layer NPA, light emitting efficiency may be increased. For example, the transmittance of light L may be reduced due to the second inorganic encapsulation layer ENI2.

In an embodiment of the inventive concept, the thickness E-TH1 of a portion of the second inorganic encapsulation layer ENI2 overlapping the light-emitting region PA may be reduced. Therefore, since the transmittance of the light L passing through the second inorganic encapsulation layer ENI2 is increased, the light emitting efficiency may be increased.

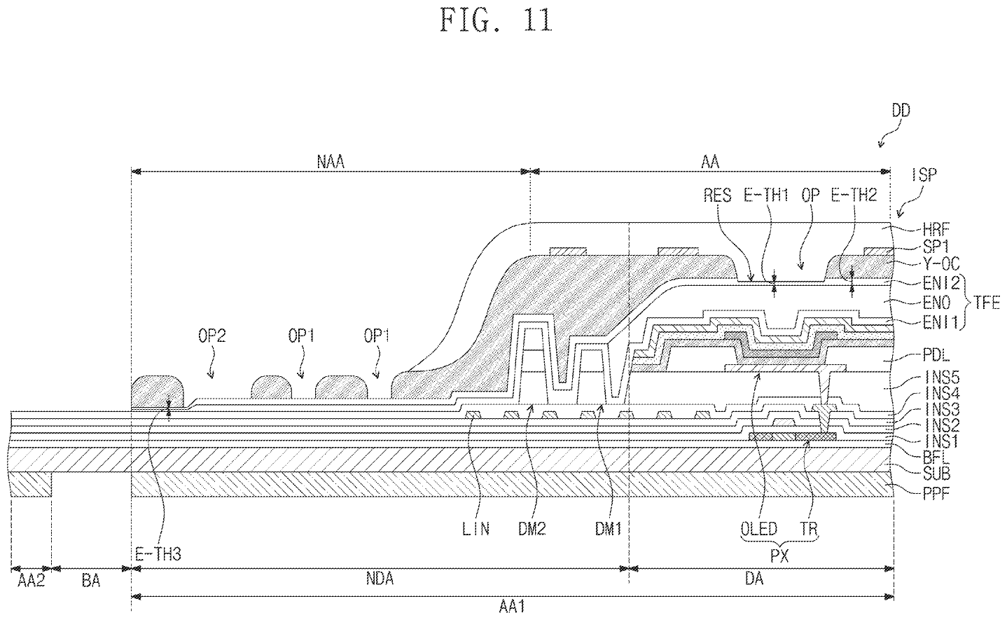

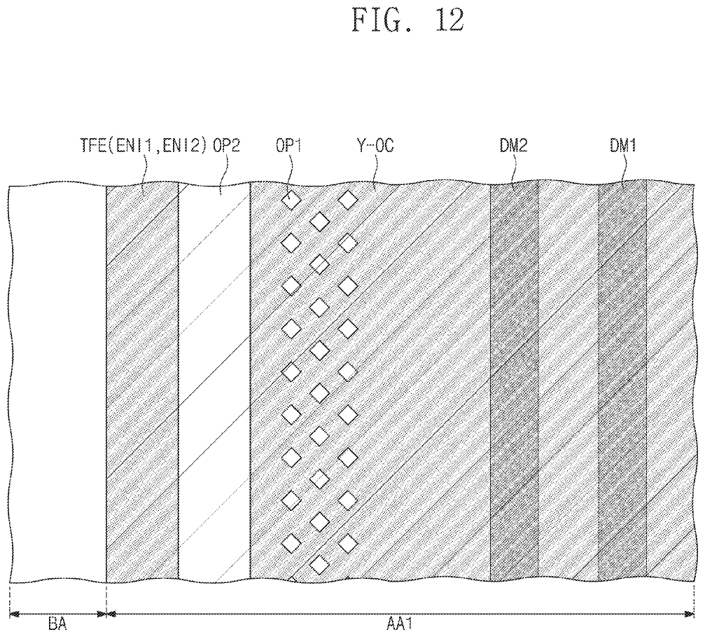

FIG. 11 illustrates a cross-section of the bending region BA and the first and second regions AA1 and AA2 adjacent to the bending region BA illustrated in FIGS. 4 and 6 according to an embodiment of the inventive concept. FIG. 12 is a plan view of the cover layer Y-OC defining the openings OP illustrated in FIG. 11 according to an embodiment of the inventive concept.

As an example, FIG. 11 illustrates a first sensing part SP1 of the input sensor ISP, and FIG. 12 illustrates a plane of the cover layer Y-OC between the bending region BA and a second dam DM2.

Referring to FIGS. 11 and 12, like the display panel DP, the substrate SUB may include the first region AA1 including the display region DA and the non-display region NDA, the second region AA2, and the bending region BA between the first region AA1 and the second region AA2.

A plurality of line patterns LIN disposed in the same layer as the connection electrode CNE may be disposed on the substrate SUB around a pixel PX. The line patterns LIN may be disposed on the third insulating layer INS3, and the fourth insulating layer INS4 may be disposed on the line patterns LIN. In an embodiment, the line patterns disposed in the same layer as a gate G may be further disposed on the substrate SUB.

The line patterns LIN may form the first and second control lines CSL1 and CSL2, data lines DL1 to DLn, and power lines PL1 and PL2 illustrated in FIG. 4. A panel protection film PPF may be disposed below the substrate SUB. In an embodiment, the panel protection film PPF is not disposed below the bending region BA of the substrate SUB. Since the panel protection film PPF is not disposed below the bending region BA, the bending region BA may be more easily bent.

The buffer layer BFL and the first to fourth insulating layers INS1 to INS4 may extend to the non-display region NDA, bending region BA, and second region AA2 of the substrate SUB. The fifth insulating layer INS5 and the pixel-defining film PDL may be disposed in the display region DA of the substrate SUB. The pixel PX may be disposed in the display region DA of the substrate SUB.

The display panel DP may include a first dam DM1 and the second dam DM2 disposed in the non-display region NDA of the substrate SUB. The first dam DM1 and the second dam DM2 may be disposed on the fourth insulating layer INS4 and spaced apart from each other. The first darn DM1 may be closer to the display region DA than the second dam DM2 is to the display region DA.

Each of the first darn DM1 and the second dam DM2 may include a plurality of layers stacked on each other. For example, the height of the second darn DM2 may be greater than that of the first darn DM1. However, the height of the second darn DM2 and the height of the first dam DM1 are not limited thereto.

The thin-film encapsulation layer TFE may be disposed in the first region AA1 of the substrate SUB. For example, the thin-film encapsulation layer TFE disposed in the display region DA of the substrate SUB so as to cover the pixel PX may extend toward the non-display region NDA. The thin-film encapsulation layer TFE may be disposed on the fourth insulating layer INS4 so as to cover the first and second dams DM1 and DM2.

The first inorganic encapsulation layer ENI1 disposed on the pixel PX may extend toward the non-display region NDA. The first inorganic encapsulation layer ENI1 may extend above the fourth insulating layer INS4 and the first and second dams DM1 and DM2. The first inorganic encapsulation layer ENI1 may be disposed on the fourth insulating layer INS4 so as to cover the first and second dams DM1 and DM2.

The second inorganic encapsulation layer ENI2 may be disposed on the first inorganic encapsulation layer ENI1. When viewed on a plane, an organic encapsulation layer ENO may overlap the display region DA and be disposed between the first inorganic encapsulation layer ENI1 and the second inorganic encapsulation layer ENI2.

The first and second darns DM1 and DM2 may define a region in which the organic encapsulation layer ENO including an organic material is formed. An organic material having fluidity may be hardened to form the organic encapsulation layer ENO. Although an organic material having fluidity flows toward the non-display region NDA, the organic material may be blocked by the first darn DM1. Accordingly, the organic encapsulation layer ENO may be disposed up to the first dam DM1. The second darn DM2 may additionally block the organic material that overflows the first dam DM1.

The first inorganic encapsulation layer ENI1 and the second inorganic encapsulation layer ENI2 may come in contact (e.g., direct contact) with each other in the non-display region NDA of the substrate SUB. For example, the first inorganic encapsulation layer ENI1 and the second inorganic encapsulation layer ENI2 may be separated from each other by the organic encapsulation layer ENO in the display region DA, and may come into direct contact with each other in the non-display region NDA. The first inorganic encapsulation layer ENI1 and the second inorganic encapsulation layer ENI2 coming into contact with each other may be disposed adjacent to the bending region BA.

In the first region AA1 adjacent to the bending region BA, the first inorganic encapsulation layer ENI1 and the second inorganic encapsulation layer ENI2 may be disposed on the fourth insulating layer INS4. As an example, FIG. 12 illustrates the first and second inorganic encapsulation layers ENI1 and ENI2 as diagonal lines.

A third thickness E-TH3 of each of portions of the first and second inorganic encapsulation layers ENI1 and ENI2 adjacent to the bending region BA may be smaller than the thickness of each of the first and second inorganic encapsulation layers EMI1 and ENI2 disposed in the display region DA. For example, the third thickness E-TH3 of each of a portion of the first inorganic encapsulation layer ENI1 and a portion of the second inorganic encapsulation layer ENI2 adjacent to the bending region BA may be smaller than the second thickness E-TH2.

As an example, the second thickness E-TH2 may be about 5000 to about 6000 angstroms, and the third thickness E-TH3 may be about 100 to about 500 angstroms. In addition, the third thickness E-TH3 may be different from the first thickness E-TH1. The sum of the third thicknesses E-TH3 of the first inorganic encapsulation layer ENI1 and the second inorganic encapsulation layer ENI2 adjacent to the bending region BA may be smaller than the second thickness E-TH2 of the second inorganic encapsulation layer ENI2.

To form the first inorganic encapsulation layer ENI1 and the second inorganic encapsulation layer ENI2, particles including an inorganic material may be provided on the substrate. Ideally, the inorganic material may be provided to a portion of the display region DA and the no display region NDA adjacent to the display region DA. A mask for depositing the inorganic material may be used, and the inorganic material may be provided through the opening of the mask to the portion of the display region DA and the non-display region NDA adjacent to the display region DA.

However, due to a process error, some of the inorganic material may be provided to a portion adjacent to the bending region BA. For example, the inorganic material may be provided outside the opening of the mask so that an unintended thin film may be formed in a portion adjacent o the bending region BA.

In this case, the inorganic material provided to the portion of the display region DA and the non-display region NDA adjacent to the display region DA may be deposited in a normal thickness, but the inorganic material provided to the portion adjacent to the bending region BA may be deposited in a relatively thin thickness. Accordingly, the third thickness E-TH3 may be smaller than the second thickness E-TH2.

As illustrated in FIGS. 8 and 10, a portion of the second inorganic encapsulation layer ENI2 overlapping each of the openings OP may be etched so that the thickness of the portion of the second inorganic encapsulation layer ENI2 overlapping each of the openings OP may be smaller. In this case, the third thickness E-TH3 may be different from the first thickness E-TH1. For example, the third thickness E-TH3 may be greater or smaller than the first thickness E-TH1, or may be about the same as the first thickness E-TH1.

The cover layer Y-OC may be disposed in the first region AA1. The cover layer Y-OC disposed in the display region DA of the substrate may extend to the non-display region NDA so as to be adjacent to the bending region BA. The over layer Y-OC may cover the first and second dams DM1 and DM2.

The cover layer Y-OC may provide a substantially flat upper surface on a portion of the display region DA and the non-display region NDA adjacent to the display region DA. The first sensing parts SP1 may be disposed on the flat upper surface of the cover layer Y-OC.

Accordingly, the first sensing parts SP1 may be disposed on a portion of the display region DA and the non-display region NDA adjacent to the display region DA. As a result, the active region AA of the input sensor ISP may be further expanded than the display region DA, and some of the first sensing parts SP1 may be disposed on the first and second dams DM1 and DM2.

A plurality of first openings OP1 and a second opening OP2 may be defined in a portion of the cover layer Y-OC between the bending region BA and the second dam DM2. The first openings OP1 may be arranged adjacent to and along the second dam DM2. When viewed on a plane, the first openings OP1 may have a rhombus shape. However, the shape of the first openings OP1 is not limited thereto. The first openings OP1 may be arranged in a matrix form.

The second opening P2 may be adjacent to the bending region BA. The second opening OP2 may extend in one direction. The second opening OP2 may extend along the second dam DM2. The refracting layer HRF may be disposed on the cover layer Y-OC so as to cover the first sensing parts SP1. The refracting layer HRF may be disposed in the display region DA. The refracting layer HRF may be spaced apart from the bending region BA and disposed in the non-display region NDA.

The first openings OP1 may be disposed between the second opening OP2 and the second darn DM2, and the second opening OP2 may be disposed between the bending region BA and the first openings OP1.

An organic material may be hardened to form the refracting layer HRF. When an organic material for forming the refracting layer HRF is excessively provided on the cover layer Y-OC, the organic material having fluidity may flow toward the bending region BA. In this case, the organic material may be accommodated in the first and second openings OP1 and OP2 and may not flow toward the bending region. The first and second openings OP1 and OP2 may serve to block the organic material provided on the cover layer Y-OC from flowing to an unintended place.

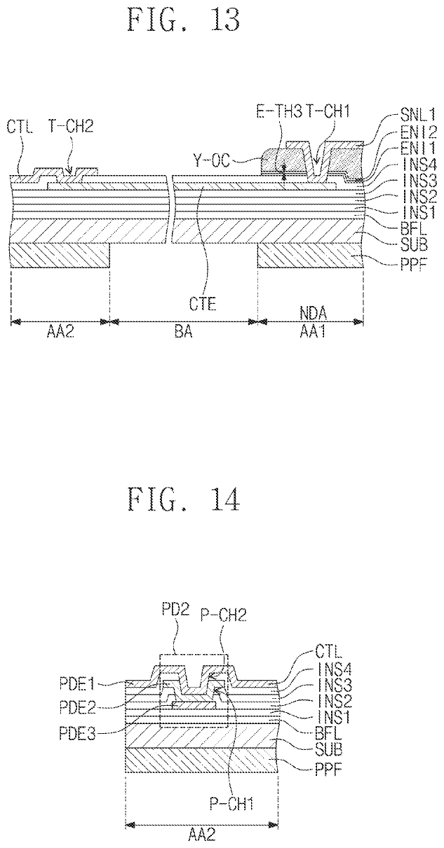

FIG. 13 is a cross-sectional view illustrating a connection structure of the first signal line SNL1, in which the connection structure extends the first signal line SNL1 to the second region AA2 via the bending region BA illustrated in FIG. 6, according to an embodiment of the inventive concept. FIG. 14 is a cross-sectional view illustrating a connection structure of the second pad PD2 illustrated in FIG. 6 according to an embodiment of the inventive concept.

Referring to FIG. 13, a connection electrode CTE may be disposed in the non-display region NDA of the first region AA1. The connection electrode CTE may be spaced apart from the pixel PX and the first and second dams DM1 and DM2 illustrated in FIG. 11 and may be disposed in the non-display region NDA.

The connection electrode CTE may extend to the bending region BA. The connection electrode CTE may extend to the second region AA2 via the bending region BA. For example, the connection electrode CTE may extend to a portion of the second region AA2 adjacent to the bending region BA.

The connection electrode CTE may be disposed on the third insulating layer INS3, and the fourth insulting layer INS4 may be disposed on the third insulating layer INS3 so as to cover a portion of the connection electrode CTE. The connection electrode CTE may be simultaneously formed of the same material as the connection electrode CNE illustrated in FIG. 5 and may be disposed in the same layer as the connection electrode CNE. The connection electrode CTE may be closer to the bending region BA than the first and second dams DM1 and DM2.

The first and second inorganic encapsulation layers ENI1 and ENI2 may extend above the connection electrode CTE and be disposed adjacent to the bending region BA. As described above, each of the first and second inorganic encapsulation layers disposed on the connection electrode CTE may have the third thickness E-TH3.

The first signal line SNL1 connected to the first sensing part SP1 may be connected to the connection electrode CTE. Therefore, the first sensing part SP1 may be electrically connected to the connection electrode CTE through the first signal line SNL1.

The first signal line SNL1 may be connected to the connection electrode CTE through a first contact hole T-CH1 defined in the first and second inorganic encapsulation layers ENI1 and ENI2 and the fourth insulating layer INS4. That is, the first sensing part SP1 may be connected to the connection electrode CTE through the first contact hole T-CH1.

A connection line CTL may be disposed in the second region AA2. The connection line CTL may be disposed on the fourth insulation layer INS4. The connection line CTL may be connected to the connection electrode CTE through a second contact hole T-CH2 defined in the fourth insulating layer INS4 in a portion of the second region AA2 adjacent to the bending region BA. The connection line CTL may extend toward the second pad PD2 illustrated in FIG. 6.

The connection electrode CTE and the connection line CTL may be structures that extend the first signal line SNL1 to the bending region BA and the second region AA2. Therefore, the first signal line SNL1 may extend to the second region AA2 via the bending region BA through the connection electrode CTE and the connection line CTL.

Referring to FIG. 14, the connection line CTL may extend toward and be connected to the second pad PD2. Therefore, the connection electrode CTE may be electrically connected to the second pad PD2 through the connection line CTL.

The second pad PD2 may include a first pad electrode PDE1, a second pad electrode PDE2 disposed below the first pad electrode PDE1, and a third pad electrode PDE3 disposed below the second pad electrode PDE2. The first pad electrode PDE1 may he defined as a portion of the connection line CTL adjacent to the end of the connection line CTL.

The second pad electrode PDE2 may be simultaneously formed of the same material as the connection electrode CNE illustrated in FIG. 5 and may be disposed in the same layer as the connection electrode CNE. The third pad electrode PDE3 may be simultaneously formed of the same material as the gate G illustrated in FIG. 5 and may be disposed in the same layer as the gate G. In an embodiment, the third pad electrode PDE3 may be omitted.

The second pad electrode PDE2 may be connected to the third pad electrode PDE3 through a first contact hole P-CH1 defined in the second and third insulating layers INS2 and INS3. The first pad electrode PDE1 may be connected to the second pad electrode PDE2 through a second contact hole P-CH2 defined in the fourth insulating layer INS4.

As an example, the structure of the first signal line SNL1 and the second pad PD2 illustrated in FIG. 6 has been described. According to embodiments, the second signal line SNL2 and the third pad PD3 may also have substantially the same connection structure as the first signal line SNL1 and the second pad PD2.

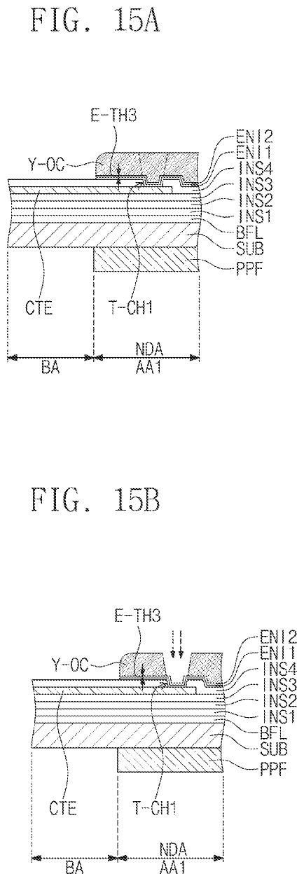

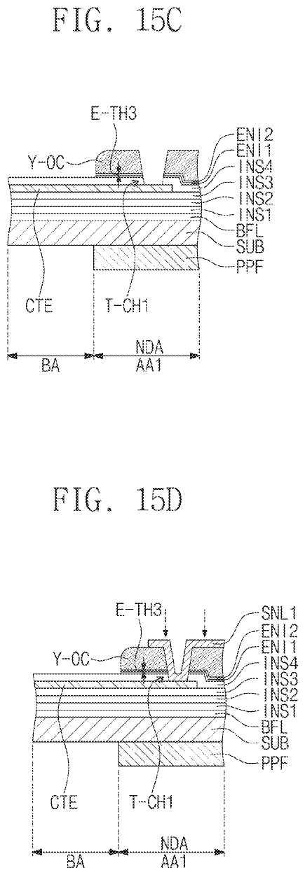

FIGS. 15A to 15D are cross-sectional views illustrating the non-display region NDA adjacent to the bending region BA illustrated in FIG. 13 according to an embodiment of the inventive concept, and are referred to in describing an effect of the implementation of the cover layer Y-OC used in FIG. 13.

Referring to FIG. 15A, as described above, when manufacturing the display device DD, the first and second inorganic encapsulation layers ENI1 and ENI2 may be provided to a portion adjacent to the bending region BA due to a process error. In this case, the first and second inorganic encapsulation layers ENI1 and ENI2 may close the first contact hole T-CH1.

Due to the first and second inorganic encapsulation layers ENI1 and ENI2 disposed in the first contact hole T-CH1, the first signal line SNL1 may not be connected to the connection electrode CTE. To prevent this from occurring, a cover layer Y-OC, which is an organic layer, may be used.

Referring to FIGS. 15A and 15B, the cover layer Y-OC may be disposed on the first and second inorganic encapsulation layers ENI1 and ENI2 in the first region AA1 adjacent to the bending region BA. A portion of the cover layer Y-OC overlapping the first contact hole T-CH1 defined in the fourth insulating layer INS4 may be removed. Therefore, portions of the first and second inorganic encapsulation layers ENI1 and ENI2 overlapping the first contact hole T-CH1 may be exposed.

Referring to FIGS. 15B and 15C, portions of the first and second inorganic encapsulation layers ENI1 and ENI2 exposed by removal of the cover layer Y-OC may be removed by a dry etching method using the cover layer Y-OC as a mask. Therefore, the first contact hole T-CH1 may be defined in the cover layer Y-OC, the first and second inorganic encapsulation layers ENI1 and EN12, and the fourth insulating layer INS4.

Referring to FIGS. 8 and 11 described above, the second thickness E-TH2 may be greater than the third thickness E-TH3, and the sum of the third thicknesses E-TH3 of the first and second inorganic encapsulation layers ENI1 and ENI2 disposed on the connection electrode CTE may be smaller than the second thickness E-TH2. Therefore, although portions of the first and second inorganic encapsulation layers ENI1 and ENI2 adjacent to the bending region BA are etched and removed, any portion of the second inorganic encapsulation layer ENI2 disposed on the pixel PX and overlapping the opening OP may not be etched.

Referring to FIG. 15D, after portions of the first and second inorganic encapsulation layers ENI1 and ENI2 overlapping the first contact hole T-CH1 have been removed, the first signal line SNL1 may be provided on the cover layer Y-OC and connected to the connection electrode CTE through the first contact hole T-CH1.

FIG. 16 illustrates a cross-section of the camera CAM and the surroundings of the camera CAM illustrated in FIG. 1 according to an embodiment of the inventive concept.

Referring to FIG. 16, a transistor TR may be connected to a light-emitting diode OLED through a first connection electrode CNE1 and a second connection electrode CNE2. Unlike the structure illustrated in FIG. 5, two connection electrodes CNE1 and CNE2 may be used. The first connection electrode CNE1 may be disposed on the third insulating layer INS3, and the fourth insulating layer INS4 may be disposed on the first connection electrode CNE1 and the third insulating layer INS3.

A fifth insulating layer INS5 may be disposed on the fourth insulating layer INS4, and the second connection electrode CNE2 may be disposed on the fifth insulating layer INS5. A sixth insulating layer INS6 may be disposed on the second connection electrode CNE2 and the fifth insulating layer INS5. The fifth and sixth insulating layers INS5 and INS6 may be organic layers. The light-emitting diode OLED may be disposed on the sixth insulating layer INS6.

The first connection electrode CNE1 may be connected to the transistor TR through a first contact hole CH1 defined in the first, second, and third insulating layers INS1, INS2, and INS3. The second connection electrode CNE2 may be connected to the first connection electrode CNE1 through a third contact hole CH3 defined in the fourth and fifth insulating layers INS4 and INS 5. The second electrode CNE2 may be connected to the light-emitting diode OLED through the second contact hole CH2 defined in the sixth insulating layer INS6.

A hole H may be defined in the display panel and the input sensor ISP, and the camera CAM may be disposed in the hole H. A groove GV may be defined on the upper surface of the substrate SUB around the hole H. The groove GV may be one of a plurality of grooves GV. The groove GV may include a first groove GV1 and a plurality of second grooves GV2. The first groove GV1 and the second grooves GV2 may have a closed-line shape surrounding the hole H.

Each of the first groove GV1 and the second grooves GV2 may be defined as being depressed by a predetermined depth from the upper surface of the substrate SUB to the lower portion thereof. Each of the first groove GV1 and the second grooves GV2 may be formed by removing portions of the substrate SUB. The first groove GV1 may be adjacent to a pixel PX and the second grooves GV2 may be adjacent to a hole H.

Deposition patterns ELP may be disposed in the first groove GV1 and the second grooves GV2. The deposition patterns ELP may include the same materials as the hole control layer HCL, the electron control layer ECL, and the second electrode CE of the light-emitting diode OLED illustrated in FIG. 5, and be formed together when the hole control layer HCL, the electron control layer ECL, and the second electrode CE are formed. The deposition patterns ELP may be covered by the first inorganic encapsulation layer ENI1 and the second inorganic encapsulation layer ENI2.

In an embodiment, the deposition patterns ELP are not continuously disposed from the light-emitting diode OLED. Continuity between the deposition patterns ELP and the light-emitting diode OLED may be blocked by the first groove GV1 and the second grooves GV2. In an embodiment, the deposition patterns ELP are not continuously disposed with each other, but rather, may be disposed spaced apart from each other.

To form a hole H, a portion of the display panel DP may be cut off. During the cutting process, external moisture or oxygen may be introduced into the display panel DP through the cutting surface of the hole. When the deposition pattern ELP extends from the light-emitting diode OLED and is disposed up to the hole H, external moisture or oxygen which has entered through the hole H may penetrate into the pixels PX through the deposition pattern ELP. The pixels PX may be damaged by such moisture or oxygen.

However, in an embodiment of the inventive concept, the deposition patterns ELP are spaced apart from the light-emitting diode OLED, and since the deposition patterns ELP are also spaced apart from each other, external moisture or oxygen which has entered through the hole H may be blocked.

A dam DM1_1 may be disposed on the substrate between the first groove GV1 and a second groove GV2 adjacent to the first groove GV1. In an embodiment, the deposition patterns ELP are not disposed on the dam DM1_1. The darn DM1_1 may be formed of the buffer layer BFL, the first to sixth insulating layers INS1 to INS6, the pixel-defining film PDL, and an additional spacer disposed on the pixel-defining film PDL.

The buffer layer BFL may be disposed on the substrate SUB between the second grooves GV2. In an embodiment, the deposition patterns ELP are not disposed on the buffer BFL between the second grooves GV2.

The cover layer Y-OC may be disposed on the deposition patterns ELP. The cover layer Y-OC may be disposed on the first and second grooves GV1 and GV2. The refracting layer HRF may be disposed on the cover layer Y-OC.

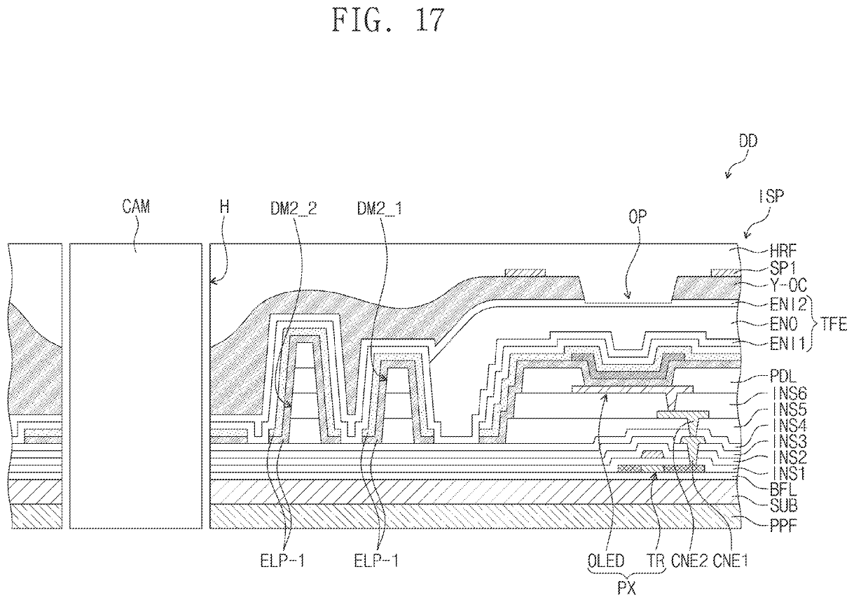

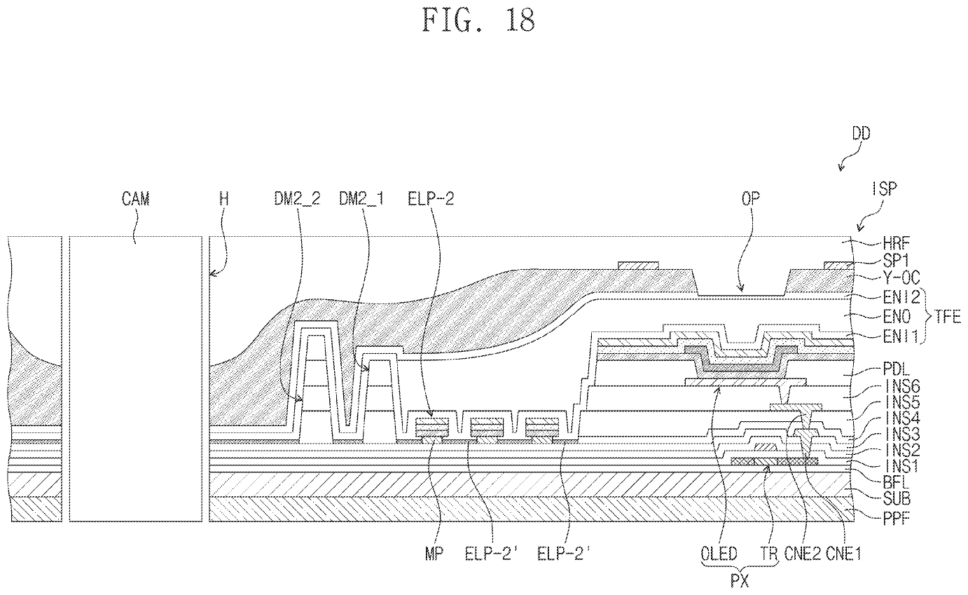

FIG. 17 illustrates a cross-section of the camera CAM and the surroundings of the camera CAM illustrated in FIG. 1 according to an embodiment of the inventive concept.

Hereinafter, the differences between the configuration illustrated in FIG. 17 and the configuration illustrated in FIG. 16 will be mainly described, and a further description of components and technical aspects previously described will be omitted.

Referring to FIG. 17, a plurality of dams DM2_1 and DM2_2 may be disposed on the substrate SUB around a hole H. The dams DM2_1 and DM2_2 may include a first dam DM2_1 adjacent to a pixel PX and a second dam DM2_2 adjacent to the hole H. The second dam DM2_2 may be disposed between the hole H and the first dam DM2_1.

The height of the second dam DM2_2 may be greater than that of the first dam DM2_1. For example, the first dam DM2_1 may be formed of the fifth and sixth insulating layers INS5 and INS6 and the pixel-defining film PDL. The second dam DM2_2 may be formed of the fifth and sixth insulating layers INS5 and INS6, the pixel-defining film PDL, and an additional spacer disposed on the pixel-defining film PDL.

Deposition patterns ELP-1 may be disposed on the first dam DM2_1 and the second dam DM2_2. The deposition patterns ELP-1 may be disposed on the substrate SUB so as to cover the first dam DM2_1 and the second dam DM2_2.

The deposition patterns ELP-1 may include the same materials as the hole control layer HCL and the electron control layer ECL of the light-emitting diode OLED illustrated in FIG. 5, and be formed together when the hole control layer HCL and the electron control layer ECL are thrilled. The deposition patterns ELP-1 may be covered by the first inorganic encapsulation layer ENI1 and the second inorganic encapsulation layer ENI2. The cover layer Y-OC may be disposed on the first dam DM2_1, the second dam DM2_2, and the deposition patterns ELP-1.

The deposition patterns ELP-1 may be separated from the light-emitting diode OLED. In addition, the deposition patterns ELP-1 may be separated and spaced apart from each other between the first dam DM2_1 and the second dam DM2_2 and between the hole H and the second dam DM2_2. In an embodiment, the deposition patterns ELP are not continuously disposed from the light-emitting diode OLED, and the deposition patterns ELP are also not continuously disposed with each other. Therefore, external moisture or oxygen which has entered through the hole H may be blocked.

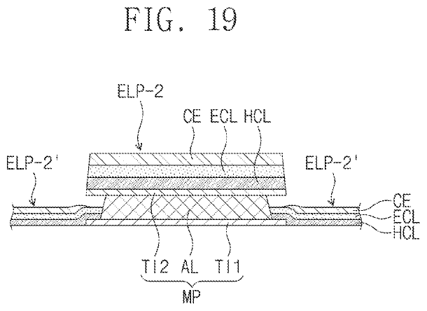

FIG. 18 illustrates a cross-section of the camera CAM and the surroundings of the camera CAM illustrated in FIG. 1 according to an embodiment of the inventive concept. FIG. 19 is an enlarged view illustrating one metal pattern illustrated in FIG. 18 according to an embodiment of the inventive concept.

Hereinafter, the differences between the configuration illustrated in FIG. 18 and the configuration illustrated in FIG. 16 will be mainly described, and a further description of components and technical aspects previously described will be omitted.

Referring to FIG. 18, the first darn DM2_1 and the second dam DM2_2 may be disposed on the substrate SUB around the hole H. Since the structures of the first dam DM2_1 and the second dam DM2_2 are the same as those of the first dam DM2_1 and the second dam DM2_2 illustrated in FIG. 17, a further explanation thereof will be omitted.

A plurality of metal patterns MP may be disposed on the substrate SUB around the hole H. The metal patterns MP may be disposed between the first dam DM2_1 and the pixel PX. The metal patterns MP may be disposed on the third insulating layer INS3. The metal patterns MP may be formed by being simultaneously patterned with the same material as the first connection electrode CNE1.

A plurality of deposition patterns ELP-2 may be disposed on the metal patterns MP. The deposition patterns ELP-2 may include the same materials as the hole control layer HCL, the electron control layer ECL, and the second electrode CE of the light-emitting diode OLED illustrated in FIG. 5, and be formed together when the hole control layer HCL, the electron control layer ECL, and the second electrode CE are formed. The deposition patterns ELP-2 may be covered by the first inorganic encapsulation layer ENI1, the second inorganic encapsulation layer ENI2, and the organic encapsulation layer ENO.

The cover layer Y-OC may be disposed on the first and second dams DM2_1 and DM2_2 and the deposition patterns ELP-2.

A plurality of sub-deposition patterns ELP-2′ may be disposed between the metal patterns MP. The sub-deposition patterns ELP-2′ may be spaced apart from the deposition patterns ELP-2. In an embodiment, the sub-deposition patterns ELP-2′ are not continuous from the deposition patterns ELP-2, but rather, may be separated from the deposition patterns ELP-2. The deposition patterns ELP-2 may be separated and spaced apart from each other. The sub-deposition patterns ELF-2′ may be separated and spaced apart from each other.

Referring to FIG. 19, the metal pattern MP may include a first metal layer TI1, a second metal layer AL disposed on the first metal layer TI1, and a third metal layer TI2 disposed on the second metal layer AL.

The first metal later TI1 may include titanium, the second metal layer AL may include aluminum, and the third metal layer TI2 may include titanium. Based on the horizontal direction, the width of each of the first metal layer TI1 and the third metal layer TI2 may be greater than that of the second metal layer AL.

The deposition pattern ELP-2 may be disposed on the third metal layer TI2. Based on the horizontal direction, the width of the deposition pattern ELP-2 may be greater than that of the second metal layer AL.

The sub-deposition pattern ELP-2′ may be formed of the same material as the deposition pattern ELP-2. For example, the sub-deposition pattern ELP-2′ may be formed of the same material as the hole control layer HCL, the electron control layer ECL, and the second electrode CE illustrated in FIG. 5.

The sub-deposition pattern ELP-2′ may be disposed below the third metal layer TI2 and adjacent to a side surface of the second metal layer AL. The sub-deposition pattern ELP-2′ may come in contact (e.g., direct contact with the side surface of the second metal layer AL.

The hole control layer HCL and the electron control layer ECL of the sub-deposition pattern ELP-2′ may come in contact (e.g., direct contact) with a side surface of the second metal layer AL, and the second electrode CE of the sub-deposition pattern ELP-2′ may be spaced apart from a side surface of the second metal layer AL. In an embodiment, the sub-deposition pattern ELP-2′ is not continuously disposed from the deposition pattern ELP-2 so as to be separated from the deposition pattern ELP-2.

Referring to FIGS. 18 and 19, in an embodiment, the deposition patterns ELP-2 and the sub-deposition patterns ELP-2′ are not continuously disposed from the light-emitting diode OLED. Since the deposition patterns ELP-2 and the sub-deposition patterns ELP-2′ are separated and spaced apart from each other, external moisture or oxygen which has entered through the hole H may be blocked.

Referring to a comparative example, due to various factors, the light emitting efficiency of pixels in a display device be reduced. In addition, the light generated from the pixels may travel to the left and right sides of the display device as well as the front side thereof. Embodiments of the inventive concept increase light emitting efficiency and front brightness, as described above.

According to an embodiment of the inventive concept, since the sensing electrodes of the input sensor are provided as a single layer to the display device, the thickness of the display device may be reduced.

According to an embodiment of the inventive concept, since the thickness of the thin film encapsulation layer overlapping each of the light-emitting regions is smaller than that of the thin-film encapsulation layer overlapping the non-light-emitting region, the light emitting efficiency of the display device may be increased.

According to an embodiment of the inventive concept, since light is reflected from a side surface of the cover layer disposed on pixels and defining an opening overlapping each of the light-emitting regions and travels upward, the front brightness of the display device may be increased.

While the present inventive concept has been particularly shown and described with reference to the embodiments thereof, it will be understood by those of ordinary skill in the art that various changes in form and detail may be made therein without departing from the spirit and scope of the present inventive concept as defined by the following claims.

What is claimed is:

1. A display device, comprising:
a substrate;
a pixel disposed on the substrate;
a thin-film encapsulation layer disposed on the pixel;
a cover layer disposed on the thin-film encapsulation layer and in which an opening is defined; and
a sensing part disposed on the cover layer,
wherein a recess part is defined on an upper surface of the thin-film encapsulation layer overlapping the opening.

2. The display device of claim 1, wherein the sensing part is provided as a single layer on the cover layer.

3. The display device of claim 1, further comprising:
a refracting layer disposed on the thin-film encapsulation layer,
wherein the refracting layer covers the cover layer and the sensing part,
wherein the refracting layer has a higher refractive index than the cover layer.

4. The display device of claim 3, wherein the cover layer and the refracting layer comprise an organic layer.

5. The display device of claim 1, wherein the pixel comprises a light-emitting diode overlapping the opening, when viewed on a plane.

6. The display device of claim 1, wherein the substrate comprises:
a first region comprising a display region and a non-display region around the display region;
a second region; and
a bending region between the first region and the second region,
wherein the thin-film encapsulation layer is disposed in the first region, and the pixel is disposed in the display region.

7. The display device of claim 6, further comprising:
a first dam and a second dam disposed in the non-display region and spaced apart from each other; and
a connection electrode disposed closer to the bending region than the first and second dams,
wherein the first dam is disposed closer to the display region than the second dam, the sensing part is connected to the connection electrode, and the connection electrode extends to the second region via the bending region.

8. The display device of claim 7, further comprising:
a plurality of first openings and a second opening defined in a portion of the cover layer disposed between the bending region and the second dam,
wherein the first openings are disposed between the second opening and the second dam, and the second opening is disposed between the bending region and the first openings.

9. The display device of claim 8, wherein the thin-film encapsulation layer comprises:
a first inorganic encapsulation layer disposed on the pixel and extending above the first and second dams and the connection electrode;
a second inorganic encapsulation layer disposed on the first inorganic encapsulation layer; and
an organic encapsulation layer overlapping the display region and disposed between the first inorganic encapsulation layer and the second inorganic encapsulation layer,
wherein the cover layer is disposed on the second inorganic encapsulation layer.

10. The display device of claim 9, wherein the sensing part is connected to the connection electrode through a contact hole defined in the cover layer and the first and second inorganic encapsulation layers.

11. The display device of claim 9, wherein the cover layer and the first and second inorganic encapsulation layers are disposed adjacent to the bending region.

12. The display device of claim 9, wherein the recess part is defined on an upper surface of the second inorganic encapsulation layer overlapping the opening.

13. The display device of claim 9, wherein a first thickness of a portion of the second inorganic encapsulation layer overlapping the opening is smaller than a second thickness of a portion of the second inorganic encapsulation layer overlapping the cover layer.

14. The display device of claim 13, wherein a third thickness of each of portions of the first and second inorganic encapsulation layers disposed on the connection electrode is smaller than the second thickness and different from the first thickness.

15. The display device of claim 7, further comprising:
a pad disposed in the second region and connected to the connection electrode.

16. The display device of claim 7, wherein the sensing part is one of a plurality of sensing parts, and the plurality of sensing parts is disposed in the display region and the non-display region adjacent to the display region.

17. The display device of claim 1, further comprising:
a hole defined in the substrate; and
a plurality of deposition patterns disposed in grooves defined on an upper surface of the substrate around the hole,
wherein the cover layer is disposed on the deposition patterns, and the deposition patterns are separated and spaced apart from each other.

18. The display device of claim 1, further comprising:
a hole defined in the substrate;
a plurality of dams disposed on the substrate around the hole; and
a plurality of deposition patterns disposed on the dams,
wherein the deposition patterns are separated and spaced apart from each other between the dams.

19. The display device of claim 1, further comprising:
a hole defined in the substrate;
a plurality of metal patterns disposed on the substrate around the hole;
a plurality of deposition patterns disposed on the metal patterns; and
a plurality of sub-deposition patterns disposed between the metal patterns,
wherein the deposition patterns and the sub-deposition patterns are separated and spaced apart from each other.

20. A display device comprising:
a substrate;
a pixel disposed on the substrate;
a connection electrode spaced apart from the pixel and disposed on the substrate;
a first inorganic encapsulation layer disposed on the pixel and extending above the connection electrode;
a second inorganic encapsulation layer disposed on the first inorganic encapsulation layer;
a cover layer disposed on the second inorganic encapsulation layer; and
a sensing part disposed as a single layer on the cover layer,
wherein the sensing part is connected to the connection electrode through a contact hole defined in the cover layer and the first and second inorganic encapsulation layers, and a thickness of a portion of the second inorganic encapsulation layer disposed on the connection electrode is smaller than a thickness of a portion of the second inorganic encapsulation layer disposed on the pixel.

21. The display device of claim 20, wherein an opening is defined in the cover layer, and a recess part is defined on an upper surface of the second inorganic encapsulation layer overlapping the opening.

22. The display device of claim 21, wherein
a first thickness of a portion of the second inorganic encapsulation layer overlapping the opening is smaller than a second thickness of a portion of the second inorganic encapsulation layer overlapping the cover layer, and
a sum of thicknesses of the first and second inorganic encapsulation layers disposed on the connection electrode is smaller than the second thickness.
